(19) United States
(12) Patent Application Publication
(10) Pub. No.: US 2025/0120020 A1
(43) Pub. Date: Apr. 10, 2025

(54) SIGNAL TRACE TRANSITION FOR HIGH DATA RATE APPLICATIONS

(71) Applicant: Marvell Asia Pte Ltd, Singapore (SG)

(72) Inventors: Fei Guo, Gloucester (CA); Muhammad Ershadul Kabir, Toronto (CA); Suresh Chandrasekhar, Milpitas, CA (US)

(21) Appl. No.: 18/911,624

(22) Filed: Oct. 10, 2024

Related U.S. Application Data
(60) Provisional application No. 63/543,476, filed on Oct. 10, 2023.

(51) Int. Cl. H05K 3/34; H05K 1/02; H05K 1/18

(52) U.S. Cl. CPC H05K 3/3436; H05K 1/0224; H05K 1/181; H05K 2201/09227; H05K 2201/10734

(57) ABSTRACT

Systems, methods, and apparatus are described herein for maintaining high signal integrity and high bandwidth in data transmissions between an integrated circuit package and a PCB. The integrated circuit package has multiple layers. Signal pins for connecting the integrated circuit package, both physically and electrically, to the PCB are located at a first layer. A signal trace is coupled to each signal pin. The signal trace bifurcates into two branches and couples to a given signal pin at the distal end of each branch.

### CROSS REFERENCE TO RELATED APPLICATIONS

This disclosure claims the benefit of copending, commonly-assigned U.S. Provisional Patent Application No. 63/543,476, filed Oct. 10, 2023, which is hereby incorporated by reference herein in its entirety.

### FIELD OF USE

This disclosure relates to interfaces between an integrated circuit package and a printed circuit board (PCB). More particularly, this disclosure relates to transitions between signal traces and solder pads within an integrated circuit package for communicatively coupling the integrated circuit package to a PCB in high data rate applications.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

To optimize data transmission in modern communication systems, minimizing insertion loss and signal reflection is important. This can be achieved through proper impedance matching and careful engineering of traces in an integrated circuit package or PCB. By addressing these factors, systems can maintain high signal integrity, achieve maximum bandwidth, and support high data transmission rates, which are essential for the operation of advanced digital communication devices like switches, routers, and other network infrastructure.

### SUMMARY

Systems, methods, and apparatus are described herein for maintaining high signal integrity and high bandwidth in data transmissions between an integrated circuit package and a PCB. The integrated circuit package has multiple layers. For example, a series of device layers may be separated by an appropriate number of ground plane layers. Signal pins for connecting the integrated circuit package, both physically and electrically, to the PCB are located at a first layer. A signal trace is coupled to each signal pin. The signal trace bifurcates into two branches and couples to a given signal pin at the distal end of each branch.

In some implementations, a portion of each signal trace extends along a second layer of the integrated circuit package. The second layer is at least one layer above the first layer at which the signal pins are disposed. The portion of the signal trace formed in the second layer is communicatively coupled to another portion of the signal trace in another layer through a micro-via. In some implementations, portions of the signal trace may be formed in multiple layers. A micro-via is used to connect portions of the signal trace located at different layers.

In some implementations, the layer of the integrated circuit package at which the signal trace is bifurcate is above the layer at which the signal pins are disposed. A micro-via may connect the distal end of each branch of the signal trace to the signal pin.

In some implementations, the signal pin is surrounded, in the ball grid array, by ground pins. The ground pins are configured to reduce interference on the signal pin.

In some implementations, two signal traces form a differential signal pair. Two signal pins are therefore used for communicating the signal to the PCB. The pins surrounding the two differential signal pins may be ground pins configured to reduce interference on the differential signal pin pair.

In some implementations, a void is formed in one or more layers of the integrated circuit package surrounding at least a portion of the signal trace. For example, the voice may be formed at a location directly above the signal pin and may have a diameter equal to or larger than the diameter of the signal pin. A portion of the signal trace may be formed within the void as it travels to the signal pin.

In some implementations, the signal trace has a width of 25 microns. The signal trace may be that narrow with the benefit of shielding, such as from one or more ground traces formed adjacent to the signal trace. When the signal trace enters the void and no shielding is available, the width of the signal trace may be widened to 82 microns.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 depicts an illustrative example of a transition between a single ended signal trace and a solder ball of a ball grid array, in accordance with some implementations of the subject matter of this disclosure;

FIG. 2 is a top-down view of the illustrative example of FIG. 1, in accordance with some implementations of the subject matter of this disclosure; and

FIG. 3 depicts an illustrative example of transitions between traces of a differential signal pair and respective solder balls of a ball grid array, in accordance with some implementations of the subject matter of this disclosure.

### DETAILED DESCRIPTION

In devices requiring a high data transmission rate, such as switches, circuit design must be carefully configured to allow for maximum transmission efficiency. In the context of network devices such as switches, the Nyquist frequency defines the upper bounds of the system's internal clock speeds and signaling capabilities. Switches transmit and receive data through physical media like Ethernet cables, whose bandwidth determines the maximum frequency range for signals. Higher bandwidth allows faster signal changes, and therefore higher data transmission rates, but these rates are ultimately constrained by the Nyquist frequency and the noise in the system. Thus, managing the Nyquist frequency is critical to optimizing data transmission in digital communication systems, as it directly influences the speed, accuracy, and efficiency of data transfer in both wired and wireless networks.

In digital communication and data transmission systems, the Nyquist frequency has a direct impact on determining the maximum data transmission rates. The bandwidth of a transmission channel refers to the range of frequencies that can be effectively carried without loss. The Nyquist theorem dictates that, in an ideal noiseless channel, the maximum symbol rate, i.e., the rate at which signal changes or symbols can be transmitted, is twice the bandwidth of the channel. For instance, a transmission medium with a bandwidth of 10 MHz can theoretically support a symbol rate of 20 million symbols per second.

The data rate of a transmission system is closely tied to both the symbol rate and the number of bits encoded per symbol. Advanced modulation techniques allow multiple bits to be carried per symbol, increasing the data rate beyond the basic symbol rate. However, the Nyquist frequency sets a theoretical limit on how fast data can be transmitted without error. If the effects of noise are accounted for, increasing bandwidth (and thus the Nyquist frequency) can raise data transmission rates. However, there are limits imposed by the noise characteristics of the channel.

Insertion loss and signal reflection are critical factors influencing the performance and efficiency of signal transmission in data communication systems. Insertion loss refers to the reduction in signal power that occurs as a signal passes through a transmission medium or device, such as a cable, connector, or network switch. This loss is typically caused by resistance in the transmission medium, attenuation over long distances, and the material properties of the components used. Insertion loss is particularly detrimental at higher frequencies, where signal degradation occurs more rapidly, limiting the effective bandwidth and transmission distance. Excessive insertion loss can lead to reduced signal strength, data errors, and diminished overall system performance.

Signal reflection arises when there is an impedance mismatch between different components in a transmission line, causing a portion of the signal to be reflected back toward the source instead of continuing to the receiver. These reflections can occur at points where the physical characteristics of the transmission medium change, such as at connectors, splices, or mismatched cables. Signal reflection leads to interference with the transmitted signal, creating distortion that can result in data corruption or communication errors. In severe cases, standing waves may form, further degrading the quality of the signal. Reducing signal reflection is essential for maintaining high data integrity and minimizing error rates in high-speed data transmission systems.

Both insertion loss and signal reflection contribute to a reduction in the signal-to-noise ratio (SNR), which directly affects the maximum data transmission rates achievable in a communication system. The maximum data rate increases with a higher SNR, meaning that systems with high insertion loss and signal reflection will have a diminished ability to transmit data at optimal speeds. In high-frequency systems, where data rates and bandwidth requirements are significant, even small amounts of insertion loss or signal reflection can have a substantial impact on performance.

As noted above, minimizing insertion loss and signal reflection are needed in high data rate applications. The subject matter of this disclosure enables reduced insertion loss and reduced signal reflections for high speed data transmissions between an integrated circuit package and a PCB.

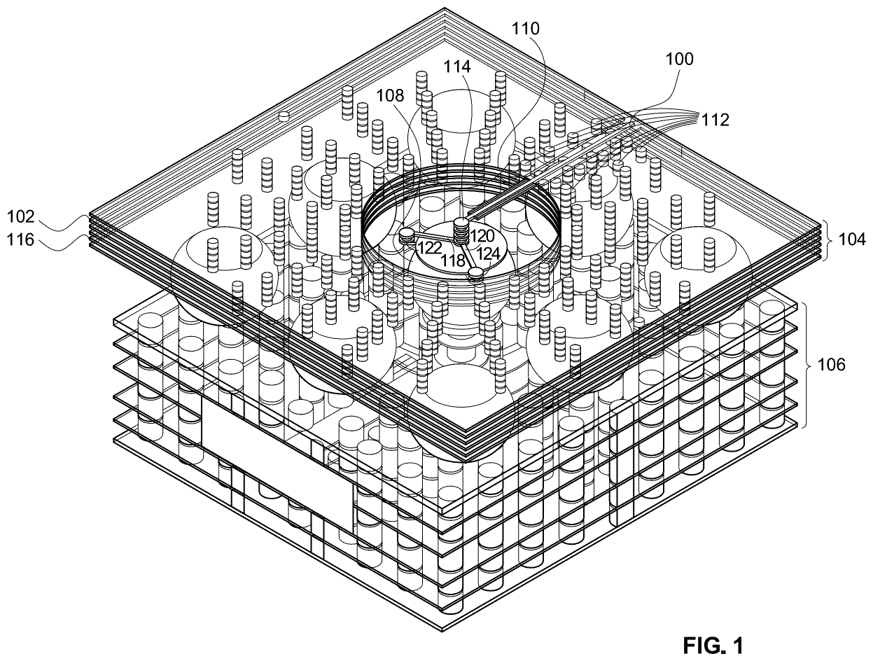

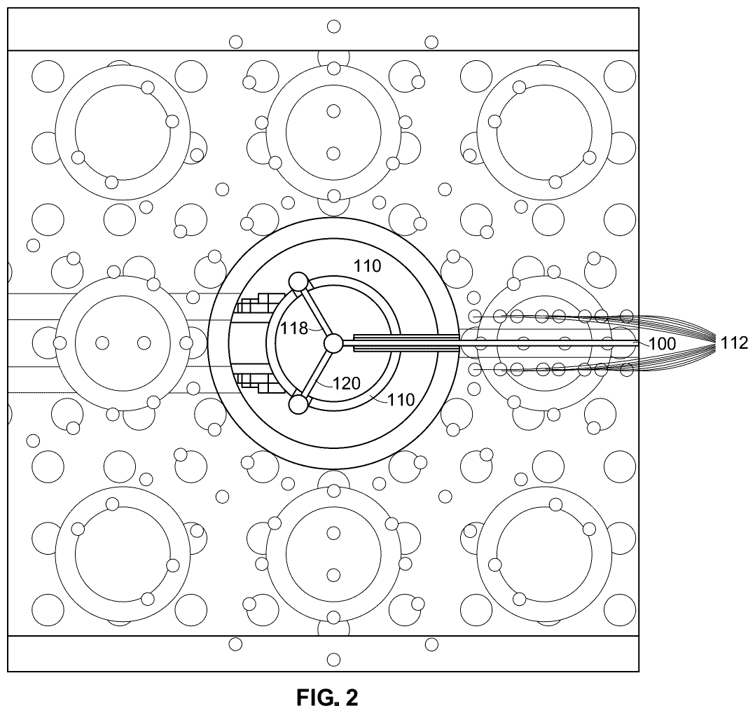

FIG. 1 depicts an illustrative example of a transition between a single ended signal trace and a solder ball of a ball grid array, in accordance with some implementations of the subject matter of this disclosure. FIG. 2 is a top-down view of the illustrative example of FIG. 1, in accordance with some implementations of the subject matter of this disclosure. A ball grid array may be used to both physically and communicatively couple an integrated circuit package to a PCB. A single ended signal trace 100 formed in a first layer 102 of an integrated circuit package 104 carries a signal from the integrated circuit package to PCB 106 via solder ball 108. A single-ended signal trace is a type of signal transmission where a single conductor, or trace, carries the signal. A reference point, typically ground, is used to measure the voltage. The signal is transmitted as the voltage difference between the trace and ground.

Single-ended traces are susceptible to noise and electromagnetic interference (EMI) because any external noise that affects the signal will also affect the ground reference. This can degrade signal integrity, especially over long distances or at high frequencies. To reduce noise, layer 102 in which signal trace 100 is formed may be disposed between two ground plane layers. Alternatively or additionally, ground traces may be formed adjacent to signal trace 100 to provide shielding from noise.

Solder ball 108 may be one of a number of solder balls in a ball grid array (BGA). To facilitate connection of signal trace 100 to solder ball 108, void 110 may be formed through at least the intervening layers of the integrated circuit package between layer 102 and solder ball 108. Void 110 ensures that the effects on signal trace 100 of any EMI generated by components of the integrated circuit package are minimized.

While still within the substrate material of layer 102, signal trace 100 may be shielded from EMI and other sources of noise by a plurality of ground traces 112. With the benefit of this shielding, signal trace 100 may be formed with a narrower width than would otherwise be necessary to maintain signal integrity. Signal trace 100 may have a width between 23.75 microns and 26.25 microns. In one implementation, signal trace 100 may have a width of 25 microns. These dimensions may differ for specific implementations and may depend on properties of the integrated circuit package such as the dielectric properties of a substrate material and/or how different layers are stacked within the integrated circuit package. Ground shielding reduces the coupling between adjacent signal traces, lowering crosstalk and preserving signal integrity even with narrower traces. Additionally, a ground plane close to the signal trace helps maintain more consistent impedance of the signal trace, even for a narrower trace width. However, when signal trace 100 proceeds through void 110, no shielding is available. To compensate, the width of signal trace 100 is increased. The increased width of signal trace 100 may be between 77.9 microns and 86.1 microns. In one implementation, the width of signal trace 100 is increased to 82 microns. These dimensions may differ for specific implementations and may depend on properties of the integrated circuit package such as the dielectric properties of a substrate material and/or how different layers are stacked within the integrated circuit package.

The majority of the portion of signal trace 100 that proceeds through void 110 maintains its widened dimensions. At point 114 corresponding to the center of solder ball 108, signal trace 100 proceeds, through one or more micro-vias, from first layer 102 to second layer 116 of the integrated circuit package above the lowest layer.

At second layer 116, the signal trace 100 bifurcates, splitting into two branches 118 and 120 at similar angles away from point 114. For example, each of branches 118 and 120 splits off at an angle of 60 degrees, leaving 120 degrees of arc between the two branches. Each of branches 118 and 120 is also formed with a width that is half of the width of the portion of signal trace 100 between the widened portion and point 114. For example, if the portion of signal trace 100 between the widened portion and point 114 has a width of 50 microns, each of branches 118 and 120 will have a width of 25 microns. Each of branches 118 and 120 extends for a length approximately equal to the radius of solder ball 108. At the distal end of each of branches 118 and 120, respective micro-vias 122 and 124 are formed to connect each respective branch to solder ball 108. In some implementations, the distal end of each branch is connected to a solder pad to which solder ball 108 is bonded, rather than directly to solder ball 108.

In one implementation, the pitch of the BGA, or the distance between solder balls measured from center to center, may be 1 mm. The diameter of void 110 is larger than the diameter of solder ball 108. For example, if the pitch of the BGA is 1 mm, each solder ball may have a diameter of 0.6 mm. Void 110 may then have a diameter between 1 mm and 1.2 mm. Other dimensions may be used for different BGA pitches. In some implementations, a small portion of signal trace 100 prior to point 114 is formed slightly narrower than the widened dimension, such as 50 microns.

This branched trace configuration results in reduced insertion loss and reduced signal reflection compared to traditional traces. The impedance of the different portions of the signal trace is reduced more gradually, resulting in fewer and smaller signal reflections, and thus better performance. For example, the impedance of the signal trace as it enters void 110 is 85 ohms. The impedance of the portion of the trace prior to point 114 may be 80 ohms. The impedance of each branch of the signal trace may be 70 ohms. Using the configuration of FIG. 1, the maximum frequency has been observed to be approximately 87 GHz. This means that up to 174 billion symbols can be transmitted every second.

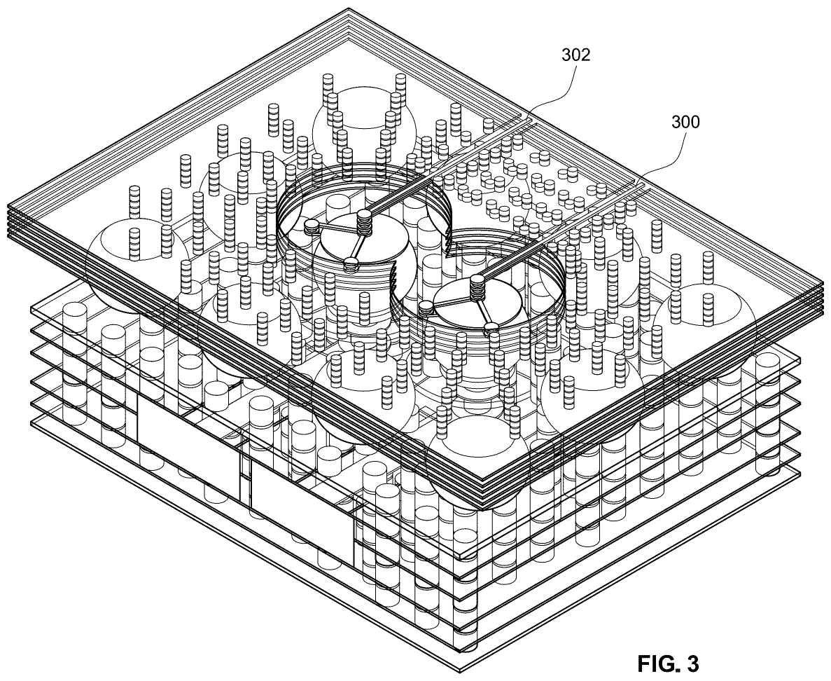

FIG. 3 depicts an illustrative example of transitions between traces of a differential signal pair and respective solder balls of a ball grid array, in accordance with some implementations of the subject matter of this disclosure. Two differential signal traces 300 and 302 are formed in a manner similar to signal trace 100 of FIG. 1. Using the configuration of FIG. 3, the maximum frequency has been observed to be approximately 80 GHz. This means that up to 160 billion symbols can be transmitted every second.

Thus it is seen that methods and systems for reducing insertion loss and signal reflections enabling higher data rates have been provided.

As used herein and in the claims which follow, the construction “one of A and B” shall mean “A or B.”

It is noted that the foregoing is only illustrative of the principles of the invention, and that the invention can be practiced by other than the described embodiments, which are presented for purposes of illustration and not of limitation, and the present invention is limited only by the claims which follow.

What is claimed is:

1. An integrated circuit package configured to optimize data transmission rates between the integrated circuit package and a printed circuit board, comprising:
a package substrate comprising a plurality of layers;
a plurality of signal pins disposed at a first layer of the plurality of layers, each signal pin in the plurality of signal pins for coupling the integrated circuit package to a printed circuit board; and
a plurality of signal traces formed in one or more layers of the plurality of layers, each respective signal trace being communicatively coupled to a respective signal pin of the plurality of signal pins, wherein each respective signal trace bifurcates into two branches, and wherein the respective signal trace is communicatively coupled to the respective signal pin at a distal end of each branch.

2. The integrated circuit package of claim 1, wherein a portion of each respective signal trace extends along a second layer of the plurality of layers, the second layer being at least one layer above the first layer of the plurality of layers, the portion of the respective signal trace being communicatively coupled to at least one other portion of the respective signal trace through a micro-via.

3. The integrated circuit package of claim 2, further comprising a micro-via between the second layer of the plurality of layers and the first layer of the plurality of layers, the second signal trace being communicatively coupled to the respective signal trace through the micro-via.

4. The integrated circuit package of claim 1, further comprising micro-vias through which the distal end of each branch is communicatively coupled to the respective signal pin.

5. The integrated circuit package of claim 1, wherein each nearest neighbor pin of the signal pin is a ground pin configured to reduce interference on the signal pin.

6. The integrated circuit package of claim 1, wherein:
the signal pin is a first signal pin in a differential signal pin pair;
a second signal pin of the differential signal pin pair is a nearest neighbor pin of the signal pin; and
all other nearest neighbor pins surrounding the first and second signal pins are ground pins.

7. The integrated circuit package of claim 1, wherein the signal trace has a width of 25 microns.

8. The integrated circuit package of claim 1, further comprising a void within the first layer surrounding at least a portion of the signal trace, wherein the portion of the signal trace is widened to 82 microns.

9. A method of fabricating an electronic device to optimize data transmission rates between the electronic device and a printed circuit board, the method comprising:
providing an integrated circuit device package having a substrate comprising a plurality of layers and a plurality of signal pins disposed at a first layer of the plurality of layers and extending in a first direction orthogonal to a surface of the integrated circuit device package; and
for each respective signal pin of the plurality of signal pins:
forming, in a second layer of the plurality of layers that is at least one layer above the first layer of the plurality of layers, a signal trace;
forming, in a third layer of the plurality of layers that is at least one layer above the first layer of the plurality of layers, two branches of the signal trace, wherein a distal end of each branch is communicatively coupled to the signal pin.

10. The method of claim 9, further comprising forming a portion of the signal trace extending along a fourth layer of the plurality of layers that is at least one layer above the first layer of the plurality of layers, the portion of the signal trace being communicatively coupled to at least one other portion of the signal trace through a micro-via.

11. The method of claim 10, further comprising forming a micro-via between the second layer and the first layer through which the signal trace is communicatively coupled with the two branches.

12. The method of claim 10, further comprising forming a micro-via between the second layer and the third layer through which the second signal trace is communicative coupled to the signal trace.

13. The method of claim 9, further comprising forming, in the lowest layer of the plurality of layers, micro-vias through which the distal end of each branch is communicatively couple to the signal pin.

14. The method of claim 9, further comprising forming a plurality of nearest neighbor pins of the signal pin as ground pins configured to reduce interference on the signal pin.

15. The method of claim 9, wherein the signal pin is a first signal pin in a differential signal pin pair, and a second signal pin of the differential pad pair is a nearest neighbor of the signal pin, the method further comprising:
forming a plurality of other nearest neighbor pins surrounding the first and second signal pins as ground pins.

16. The method of claim 9, further comprising forming the signal trace with a width of 25 microns.

17. The method of claim 9, further comprising:
forming a void within the first layer surrounding at least a portion of the signal trace; and
forming the portion of the signal trace with a width of 82 microns.

18. An apparatus configured to optimize data transmission rates between an integrated circuit package and a printed circuit board, comprising:
a printed circuit board having major plane and comprising at least one trace communicatively coupled to a respective solder ball of a ball grid array; and
an integrated circuit package configured to interface with the printed circuit board using the ball grid array, the integrated circuit package comprising:
a package substrate comprising a plurality of layers,
a plurality of signal pins disposed on a first layer of the plurality of layers, each signal pin in the plurality of signal pins extending in a first direction orthogonal to the major plane; and
a plurality of signal traces, each respective signal trace being communicatively coupled to a respective signal pin of the plurality of signal pins, wherein each respective signal trace bifurcates into two branches, a distal end of each branch being communicatively coupled to a respective signal pin.

19. The apparatus of claim 18, wherein a portion of each respective signal trace extends along a second layer of the plurality of layers, the second layer being at least one layer above the first layer of the plurality of layers, the portion of the respective signal trace being communicatively coupled to at least one other portion of the respective signal trace through a micro-via.

20. The apparatus of claim 19, further comprising a micro-via between the second layer of the plurality of layers and the first layer of the plurality of layers, the second signal trace being communicatively coupled to the respective signal trace through the micro-via.

21. The apparatus of claim 18, further comprising micro-vias through which the distal end of each branch is communicatively coupled to the respective signal pad.

22. The apparatus of claim 18, wherein each respective signal trace has a width of 25 microns.

23. The apparatus of claim 18, further comprising a plurality of voids within the first layer, each respective void surrounding at least a portion of each respective signal trace of the plurality of signal traces, wherein the portion of each respective signal trace has a width of 82 microns.
